(19) United States
(12) Patent Application Publication
(10) Pub. No.: US 2005/0034042 A1
(43) Pub. Date: Feb. 10, 2005

(54) System and method for processing and identifying errors in data

(75) Inventors: Mark Davies, Austin, TX (US); Stephen Louton, Bee Cave, TX (US); Timothy Pletcher, Austin, TX (US); James Holt, Austin, TX (US); Daniel Walters, Austin, TX (US)

Correspondence Address: FITCH EVEN TABIN AND FLANNERY, 120 SOUTH LA SALLE STREET, SUITE 1600, CHICAGO, IL, 60603-3406, US

(73) Assignee: Process Direction, LLC

(21) Appl. No.: 10/750,351

(22) Filed: Dec. 31, 2003

Related U.S. Application Data
(60) Provisional application No. 60/493,166, filed on Aug. 7, 2003.

(51) Int. Cl. G06F 11/00; G01R 31/28

(52) U.S. Cl. 714/736

(57) ABSTRACT

A system and method for determining mismatched or faulty data records in a telecommunications or other system containing large data sets from records in first and second data sets identifies potentially mismatched or faulty data records in the first data set at least in part by comparing records in the first data set to records in the second data set. The potentially mismatched or faulty records identified as potentially mismatched or faulty are verified as defective using at least one predetermined criteria.

This non-provisional application claims priority to U.S. Provisional Application No. 60/493,166, filed on Aug. 7, 2003, which is incorporated herein by reference in its entirety.

### FIELD OF THE INVENTION

The invention relates to processing information and, more specifically, to determining whether data records within sets of data include mismatched or faulty information.

### BACKGROUND OF THE INVENTION

In the telecommunication industry, stock market, retail services, and other industries, billing and other types of records are generated and maintained so that invoices or other types of information can be generated for customers. Errors may occur in these records resulting in erroneous information generated for customers.

For instance, in the telecommunication industry, call detail records (CDRs) are maintained and may include the time of a call, the length of a call, and the origination and termination points of various calls. CDRs are used to generate invoices, which are then sent to subscribers by the service provider.

For telecommunication applications, the invoice typically consists of summary data and call detail records identifying each call the user allegedly made including long distance, “1+” or other calls outbound from the customer. The invoice may also include calls received and billable to the customer, for example, toll free calls and collect calls.

The numbers of calls that occur within given time periods are typically shown on the invoice and represent the actual number of calls that were made. Further, call volume may also be shown on the invoice. This type of information represents the sum of the durations, for instance, minutes of use, of calls that were made. In addition, the total cost of all calls may be shown on the invoice. This type of information represents the total cost payable by the customer to the service provider.

One problem that has developed in the telecommunication industry is that the invoices that are generated from the CDRs may include errors. For example, the total number of calls, minutes, or cost reflected in the CDRs may not match the totals appearing in the invoice. Also, a call appearing on the invoice may be charged an incorrect rate. Among other things, these errors may result in inaccurate billing, as well as charges being billed to a customer that should not be applied.

The invoice errors are typically caused by errors in the CDRs. For example, information concerning the termination location of a call, the origination number of a call, or the origination location of call may be in error. These types of errors may result in inaccurate rating, as well as charges that should not be applied to the customer. In addition, these types of errors may indicate invalid calls or calls that are being assigned to an incorrect customer. Furthermore, incorrect decoding of the data in a CDR may occur and may result in errors in the invoice. Specifically, a CDR may be decoded to determine additional information that may be applicable to the charge for the call, and this information then replaced into the CDR before distribution to a customer. For instance, it may be determined whether a call originated and terminated within a state or other location where different, higher per minute charges may be incurred.

In telecommunication field, current systems and methods are unable to determine the nature and extent of errors and/or mismatched data elements in data records (such as vendor CDRs) and trace the errors or mismatched data elements to corresponding end-user records in a fast, cost-effective, and simple manner.

In applications involving the stock market, shares of stock are traded during the day, then cleared at night to ensure that the shares and money actually changed hands. Records are maintained regarding these transactions. Errors often occur during the day when the shares are trading. These errors may be common but minor, for instance, typing errors, or uncommon but major, such as a transaction being routed to more than one party. Currently, there is no way to validate these records and verify that the shares and money actually traded hands.

In another application, music publishers allow their music to be downloaded over the internet to customers. Records may be maintained at the internet sites used to perform the downloading. Currently, there is no way to validate these records to ensure that all downloads were correctly paid using the records.

In still another application, retailers ship millions of packages each year to customers. Records are maintained by the retailer and the shipper relating to the shipment. Currently, there is no way to identify and validate these records to ensure that the shipment has actually been completed.

### SUMMARY OF THE INVENTION

The present invention identifies mismatched and/or defective data records, such as CDRs, that may lead to billing errors in customer invoices. In other words, the present invention identifies data records where differences exist. Each information element in an invoice, for example, duration, number of calls, and time, may be validated and the inconsistent data records that lead to errors in the invoice may be identified.

In one example, the present invention may be used in telecommunication applications. For example, the records of telecommunication providers may be compared to determine if potentially erroneous records exist and to determine the nature of errors.

In another example, stock market or any other types of transactions may be matched and potentially erroneous trades identified. This may be done, for instance, by matching trades of a first party with typing errors, such as dollar values, to the most likely trade of the party's trading partner who was involved in the transaction.

In still another example, internet music publishers may validate that downloads of their music by customers have been paid for by the customers. This may be done by the music publisher comparing internally maintained records to records submitted from internet sites.

In yet another example, retailers may verify that shipments that have been billed to customers have actually been made and completed to the customer. This may be done my comparing a record in the retailer's shipping system to records at the shipping vendor.

In many of these embodiments, data records in a first data set are identified as being defective as compared to data records in a second data set. Specifically, data records in the first data set are identified as being potentially defective at least in part by comparing records in the first data set to data records in the second data set. The data records identified as potentially faulty from the first data set are verified as being defective using at least one predetermined criteria to make the determination.

In one preferred approach, a set of similarity characteristics is defined, the data records in each of the first and second sets are grouped according to the similarity characteristics into similarity groups, and the data records in the similarity groups in the first data set and the second data set are compared to obtain candidate records that are defective. Then, the candidate records are verified as being defective by determining the identity of data records in the second set that are similar to the allegedly defective record. A list of defective records and causes for the defects in the data records may be produced.

In another approach, each record in the first data set is compared against each record in the second set to determine if a complete match exists. Records with no matches are identified as candidate records that may be defective. The allegedly defective records are verified by scoring the elements of the record, mathematically combining the scores (e.g., multiplying the scores), and comparing the resultant scores to a predetermined minimum score value. If the resultant score is less than a predetermined minimum score value, the record is considered defective.

Thus, data records that are defective and lead to billing and other types of errors are quickly and easily identified. A list of defective records may be created and supplied visually to a user for further action or automatically system for further processing or action.

### BRIEF DESCRIPTION OF THE DRAWINGS

FIG. 1 is a block diagram of a system for identifying defective data records in accordance with one embodiment of the invention;

FIG. 2 is a flowchart of a method for identifying defective data records in accordance with one embodiment of the invention;

FIG. 3 is a flowchart of one aspect of a method for a top-down processing accordance with one embodiment of the invention;

FIG. 4 is a flowchart of one aspect of a method for top-down-processing in accordance with one embodiment of the invention;

FIG. 5 is a flowchart of one aspect of a method for bottom-up processing in accordance with one embodiment of the invention;

FIG. 6A-N are diagrams representing data sets as processed according to a top-down processing method in accordance with one embodiment of the invention;

FIG. 7 is a flowchart of a method for bottom-up processing in accordance with one embodiment of the invention;

FIG. 8 is a flowchart showing an example of preprocessing and calibrating a system that performs matching and verification functions in accordance with one embodiment of the invention;

FIG. 9 is a flowchart showing an example of a bottom-up process for performing matching functions in a telecommunication application in accordance with one embodiment of the invention;

FIG. 10 is a flowchart showing an example of the process of step 908 of FIG. 9 in accordance with one embodiment of the invention;

FIG. 11 is a flowchart showing an example of the process of step 1004 of FIG. 10 in accordance with one embodiment of the invention;

FIG. 12 is a flowchart showing an example of the process of step 1006 of FIG. 10 in accordance with one embodiment of the invention;

FIG. 13 is a flowchart showing an example of the process of step 1010 of FIG. 10 in accordance with one embodiment of the invention;

FIG. 14 is a flowchart showing an example of the process of step 1014 of FIG. 10 in accordance with one embodiment of the invention;

FIG. 15 is a flowchart showing an example of the process of step 1016 of FIG. 10 in accordance with one embodiment of the invention; and

FIG. 16 is a flowchart showing an example of the process of step 1018 of FIG. 10 in accordance with one embodiment of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of various embodiments of the present invention. Also, common but well-understood elements that are useful or necessary in a commercially feasible embodiment are typically not depicted in order to facilitate a less obstructed view of these various embodiments of the present invention.

### DETAILED DESCRIPTION OF THE PREFERRED EMBODIMENTS

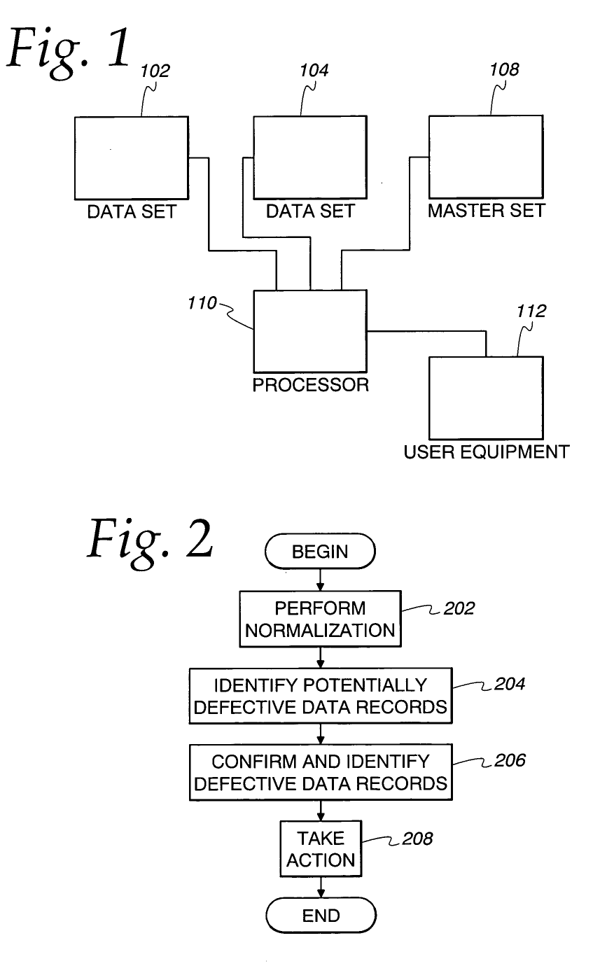

Referring initially to FIG. 1, a system for determining mismatched and/or defective data records includes a first data set 102, a second data set 104, a master data set 108, a processor 110, and a user device 112. The data sets 102, 104, and 108 may be contained on any type of memory storage device. The processor may be any type of processing device that executes computer instructions stored in a memory.

Many of the examples described herein relate to applications in the telecommunication industry. However, it will be understood that the examples are in no way limited to this industry and can be applied to many applications.

For example, in stock market applications, trades between trading partners may be matched and potentially erroneous trades identified. This may be accomplished by matching trades of a first party having errors, to the most likely trade of the party's trading partner who was involved in the transaction.

In still another example, music publishers allow customers to download music for a fee. Currently, fees are paid by the internet site operator to the publishers for all songs that are downloaded. Internet music publishers may validate that downloads of their music by customers have been paid by the customers. This may be done by the music publisher comparing internally maintained records to records submitted from internet sites.

In yet another example, retailers may verify that shipments that have been billed to customers have actually been made and completed to the customer. This may be done by comparing a record in the retailer's shipping system to records at the shipping vendor.

Returning to FIG. 1, each of the data sets 102, 104, and 108 include data records, for example CDRs. The remainder of this description uses CDRs as examples of data records. However, it will be realized that the data records are in no way limited to CDRs and may be any type of data record.

The data sets 102 and 104 represent supposedly identical data. In one example, the data set 102 may include records from telecommunication providers upon which an invoice is based and the data set 104 may include the corresponding data set from the telecommunication equipment of the end user, for instance, the customer.

The master data set 108 may be maintained at a secure site and be considered the true “untouched” data set. In other words, the master data set 108 represents a data set that is maintained, and remains unmodified. In another approach, the master data set 108 may be eliminated and one of the data sets 102 or 104 may be considered the master data set. In another approach, more data sets may be present.

The processor 110 may validate different information elements contained in an invoice that the processor 110 has received or is preparing. In a preferred approach, the processor 110 validates the total number of calls, the total volume of calls, and the total cost for the calls found in an invoice. Other types of information from the invoice may also be validated by the processor 110. The validation process may produce either an indication that the information element is valid or identify a CDR or CDRs that are potentially faulty. If mismatched or faulty CDRs are discovered, these CDRs can be removed from the data sets 102 and 104 and validation attempted again. In addition, a dispute resolution procedure may be invoked to resolve inconsistencies between the CDRs and the information element in the invoice.

In order to validate the information elements contained in the invoice, the processor 110 may determine potentially defective CDRs and then confirm that these CDRs are defective. Prior to this analysis, data normalization may be made by the processor 110 on the CDRs. For example, all times and dates may within the CDRs in the data sets 102 and 104 may be standardized to Greenwich Mean Time (GMT). Further, the data in each of the data sets 102 and 104 may be grouped according to switch (physical hardware) and the average time (and date) of a call determined. The times on the data sets 102 and 104 will then be adjusted to take into account the discrepancies between the clocks on different systems.

For each validation, potentially defective CDRs may be identified and confirmed in the data sets 102 and 104 by the processor 110 using several different methods. For instance, a “top-down” method may be used by the processor 110 to aggregate the CDRs in each of the data sets 102 and 104 into manageable groups for analysis. Then, the processor 110 may identify mismatched or faulty CDRs within the data sets 102 and 104. Next, the processor 110 may systematically analyze these groups of CDRs in ever increasing similarity levels. Specifically, the processor 110 may identify problem CDRs at a first level group, which represents the largest possible group while still allowing errors to be clearly identified. If a grouping includes apparently mismatched or faulty data, the processor subdivides the data into further subgroups at different levels until the problem CDR or CDRs are identified. The potentially mismatched or faulty CDR is then confirmed against the master set 108 (or against one of the sets 102 or 104) as being mismatched or faulty. The top-down method is described in greater detail elsewhere in this application.

In addition, a “bottom-up” method may be used to validate the elements in the invoice. Potentially defective CDRs within one of the data sets 102 or 104 are identified. Then, each potentially defective CDR is assigned a score by the processor 110 representing a probability of a match. More specifically, in one approach, the processor 110 attempts to match CDRs between the data sets 102 and 104 exactly. Then, an attempt is made to match non-exact CDRs between the data sets 102 and 104 by comparing the closeness of particular elements, such as the date/time of call, and duration of call. The bottom-up method is described in greater detail elsewhere in this application.

Further, the top-down and bottom-up methods can be combined by the processor 110 to most accurately match the data elements. For example, the first step in a matching can entail finding any exact matches, and then performing a top-down analysis on the remaining set of CDRs.

The user device 112 may be a personal computer or other similar device that allows a user to receive information concerning the detection of mismatched or faulty data and allows the configuration of system parameters. Certain variables, for example, the number of levels used in top-down analysis, are configurable by a user via the user device 112.

Referring to FIG. 2, a method for processing data to identify errors in the data, for example CDRs, is described. The method described in FIG. 2 may identify errors relating to a particular information element in an invoice, for instance, number of calls, call volume, or cost. In other words, the method described in FIG. 2 may be executed separately for each element to be validated. If not validated, CDR or CDRs that are the source of the validation error may be identified and appropriate action taken.

At step 202, normalization of the data is performed. For example, all times and dates will be standardized to GMT. In addition, the data may be grouped according to switch (i.e., the physical hardware) and the average time and date of a call determined. The times on the data sets may then be adjusted to take into account the discrepancies between the clocks on different systems.

At step 204, potentially defective records may be identified from a data set. This may be accomplished by the top-down or bottom-up grouping methods as described elsewhere in this application. In addition, a combination of these methods may be used.

At step 206, any potentially defective data records may be confirmed and identified as such to a user or system. Again, this may be according to the top-down or bottom-up methods as described elsewhere in this application. At step 208, an action may be taken in response to finding mismatched or faulty data. For example, if the data is in error, the record can be identified and removed from the data set. Customer billing information can then be determined without the mismatched or faulty data record. In addition, the cause of the error may be determined and action may be taken to ensure the type of error is prevented in the future. Further, the action may be automatically performed, for instance, by a computer, or manually performed, for example, by a human operator.

Thus, information elements in invoices may be verified and mismatched or faulty data records causing errors in the invoices may be identified. Advantageously, the exact records and elements within these records may be determined and the customer billing errors may be eliminated.

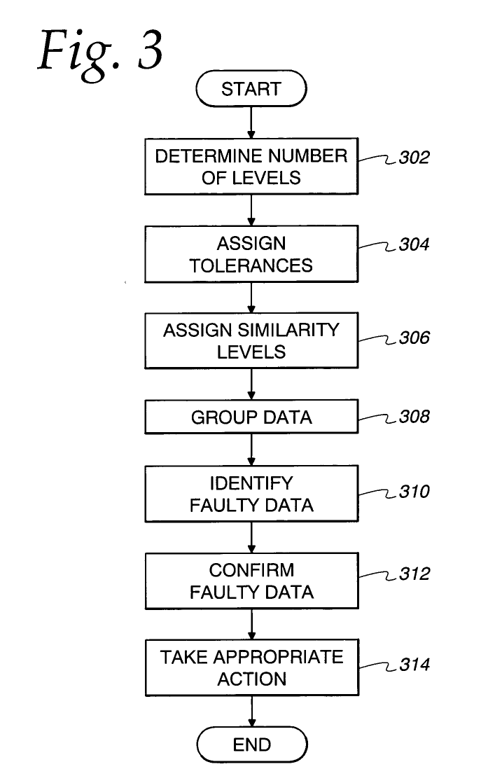

Referring now to FIG. 3, one example of the top-down grouping process for validating data is described. At step 302, the number of levels for the grouping is determined. In a preferred approach, the number of levels is a variable that is configured by the user. In telecommunication applications, the number of levels is preferably three. However, the number of levels may be varied to fit the exact application or industry.

At step 304, each level is configured with an initial tolerance level, which may be modified during the analysis. The tolerance level will define how close the different data sets must be from one another to be considered a match. For example, some levels, the tolerance may be two percent, while at others, the tolerance may be set to one percent. Still other tolerances may be set at zero percent, indicating that exact matches are required. Other examples of tolerance levels are possible.

At step 306, each data element within each data record is assigned a similarity level, which represents a group of values that will be grouped together for each level. For numerical data elements, a rounding or concatenation value may be used. For example, a value of 1406 may be rounded to 1410, or concatenated to 1400 for a similarity level of 10. For strings, the number of characters of similarity may be determined. Further, for strings, a direction of similarity, for instance, the left five characters must be identical, may be included.

At step 308, the data is grouped according to certain criteria. First level (level 1) criteria are chosen including the date and time; origination information (for outbound) or termination information (for inbound); trunk, ANI (telephone number); and location id. For outbound calls, origination is used since it will have more duplication, and therefore allows the data to be grouped into fewer groups. For inbound calls, termination will have more duplication. Jurisdiction information as determined by NPA/switch id may also be used as criteria for grouping.

In one example (having three levels) the CDRs are grouped by date and time, and concatenated by hour and origination or termination information. In other words, each CDR within a group would include elements, which fit all of these criteria.

The information element, for instance, total calls, total volume, or total cost, is determined for each group for each data set, and the values calculated for the group in the first data set are compared to those in the second data set see if they fall within tolerance. The tolerance, for example, may be set at two percent at level 1. When the calculated information element for a group in one data set varies from the equivalent group in another data set by more than two percent, the CDRs in the group are re-analyzed using the next level of analysis (level 2).

In this example, when a group 1 aggregation exceeds configured tolerances, the data will be sub-partitioned by 10 minute groupings (date and time concatenated to 10 minutes), and origination information (inbound), and termination information (outbound). A comparison is made again between the two data sets, using a new tolerance, for example, one percent. When a group 2 sub-grouping exceeds the new tolerance, the data is sub-partitioned again (level 3) into 1 minute groupings and the duration is rounded to six. At step 310, erroneous data is determined. At this point, the entries in the level 3 sub-group represents single, identical CDRs. Any data elements that do not match in this group likely represent erroneous CDRs and therefore are identified as such and passed through to the confirmation process (step 312).

At step 312, erroneous data is confirmed. The confirmation process consists of verifying CDRs which are considered erroneous against the higher level groups to validate that the data was not accidentally eliminated. For example, candidate CDRs that are potentially defective may be confirmed against CDRs in the reference data set or in the other data set.

At step 314, appropriate action is taken for the defective CDRs. For example, the erroneous CDRs are categorized according to their error, and removed from the data set. The data set is then re-validated against the tolerances. If all groupings are within acceptable tolerances, the system may be configured to rerun the data set with tighter tolerances to quickly find and eliminate problem records.

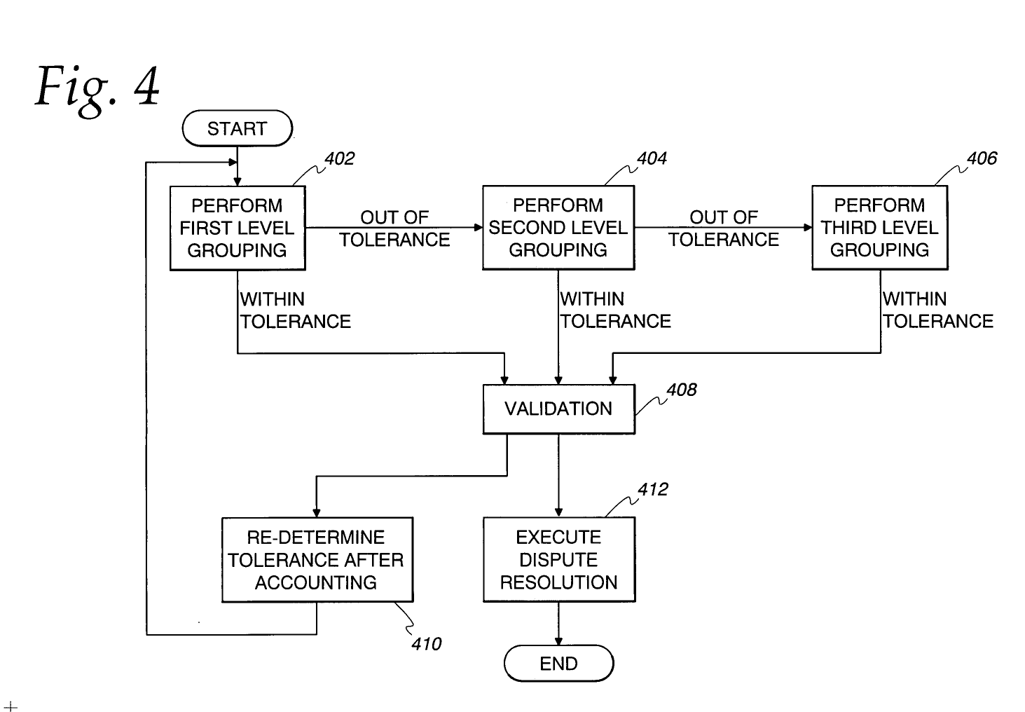

Referring to FIG. 4, an example of a top-down validation process is described. It will be realized that the process described in FIG. 4 may vary and that the number of levels, field names, fields analyzed and compared, tolerance values, and other criteria may be changed and may be application dependent.

At step 402, data is grouped at a first level based upon, date, hour, originating information, and jurisdiction. An information element from an invoice, for example, call duration, is calculated for all CDRs in the group in each data set. The calculated values are compared against a tolerance. If out of tolerance, then control is passed to step 404. If the values are within tolerance, control continues at step 408.

In one example, all records with the same date, hour, originating information and jurisdiction are placed in the same group. This grouping is done for both the first and subsequent data sets. The duration for each record in each of the first and second data sets is obtained and a total duration is calculated for all records in the group for the group within the first data set and the group in the second data set. Then, the totals may be compared against a predetermined tolerance for the first level. If outside the tolerance, a second level grouping is performed. If within the tolerance, confirmation is performed.

At step 404, new sub-groupings are made that correspond to a second level of analysis. For example, groupings may be made according to ten minutes periods of time, origination information, and termination information. Again, an information element from an invoice, for example, call duration, is calculated for all CDRs in the sub-group in each data set. The calculated values are compared against a tolerance, this time, a second level tolerance. If out of tolerance, then control is passed to step 406. If the values are within tolerance, control continues at step 408.

If the answer is negative, at step 406, new sub-groupings are determined to correspond to a third level. The sub-groups formed now represent identical CDRs. Any data elements that do not match in this group likely represent erroneous CDRs. At the completion of step 408, erroneous CDRs have been specifically identified in a particular data set.

At step 408, confirmation is performed. The questionable CDRs in a data set are compared against CDRs in the other data set (or a reference data set). First, a comparison is made of the questionable CDRs to find an identical CDR. If not found, the other data set is searched ignoring one field to see if a match is found. For instance, the time field is ignored and all CDRs with every field the same except time, are found. The process of searching by ignoring one field continues until a match is found or all CDRs have been reviewed.

If no matches are found, two fields may be ignored and the other data set searched for matching CDRs. However, any matching CDRs that are found may be regarded as defective and is eliminated from the data set and reported as being completely invalid. However, an automatic defective determination need not be made, depending upon the application, for example.

At step 410, the system may be reconfigured to re-run the remaining CDRs using tighter tolerances. Alternatively, the next analysis of an invoice information element, for example, cost may be performed.

At step 412, a dispute resolution process may be executed. For example, a report of mismatched or faulty CDRs may be issued along with the reasons for the errors in the CDRs. A user may take further corrective actions based upon the report.

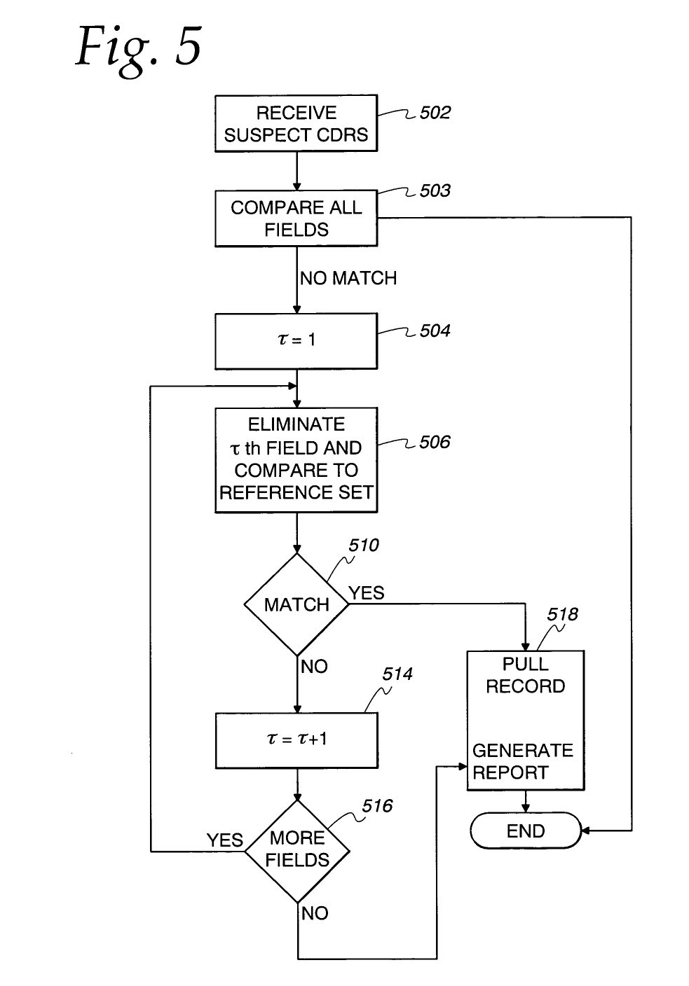

Referring now to FIG. 5, one example of a confirmation process according to a bottom-up method is described. This process is executed for each of the potentially mismatched or faulty CDRs. At step 502, the CDRs are received. The suspect CDRs are CDRs that have been identified as potentially mismatched or faulty in a first data set after the grouping process has been performed. At step 503, a comparison is made between the suspect CDR in the first data set to see if an identical CDR exists in the second data set. If a match is made, then the record is likely to be non-faulty. Otherwise, control continues at step 504.

At step 504, a variable is set to one. The variable represent the number of a field within the CDR and will be incremented as fields are ignored and CDRs compared in the remaining steps.

At step 506, the ith field is eliminated and a comparison is made between the suspect CDR and CDRs in the second data set. If a match is detected, at step 508, the CDR is removed from the data set and the CDR is marked as mismatched or faulty. Otherwise, if no match is found, the variable I is incremented at step 514 and it is determined if more fields (to be ignored) exist at step 516.

If more fields exist, control continues at step 506. Otherwise, at step 518, the record is omitted from each data set and a report is generated showing the CDRs that are mismatched or faulty and the reasons for this determination. In addition, the process can be repeated by ignoring two fields and comparing the potentially mismatched or faulty CDRs to the CDRs in the second data set. However, matches are found after this step, then the CDR can be assumed to be invalid.

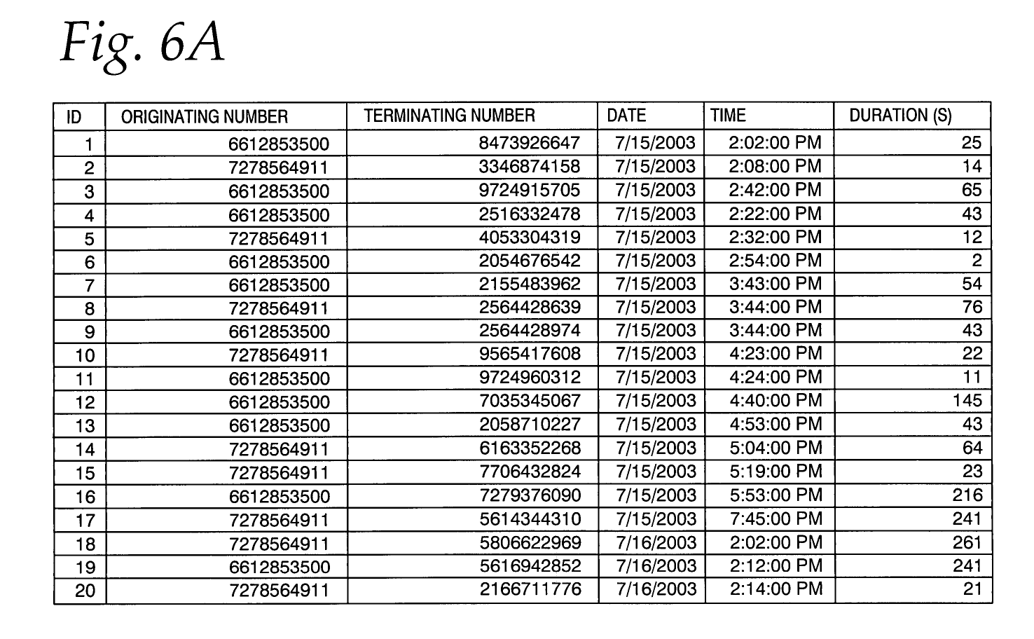

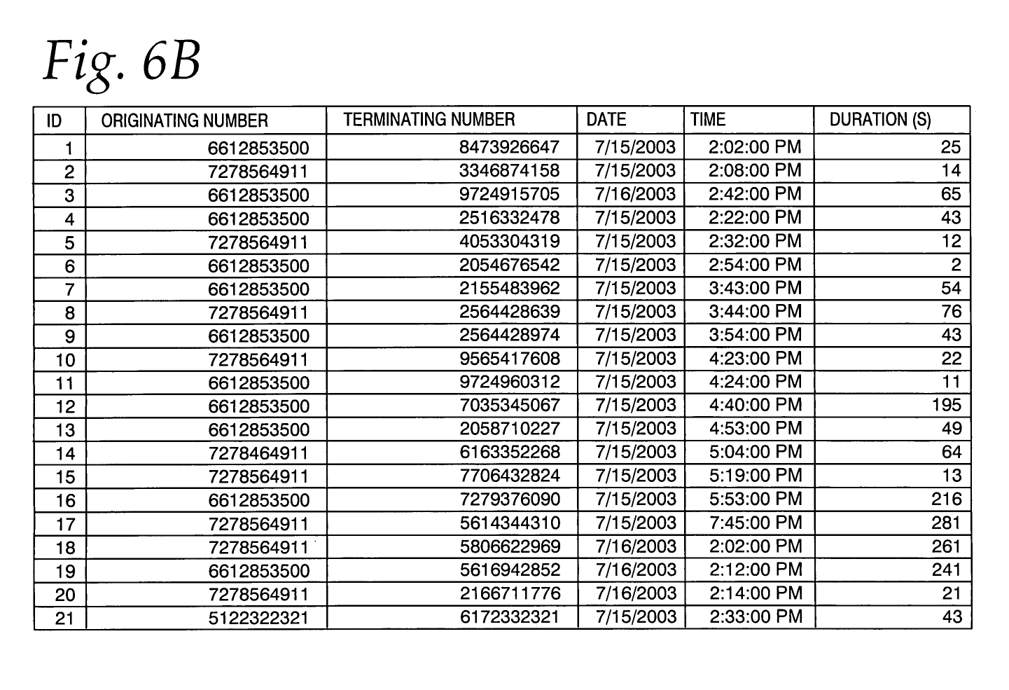

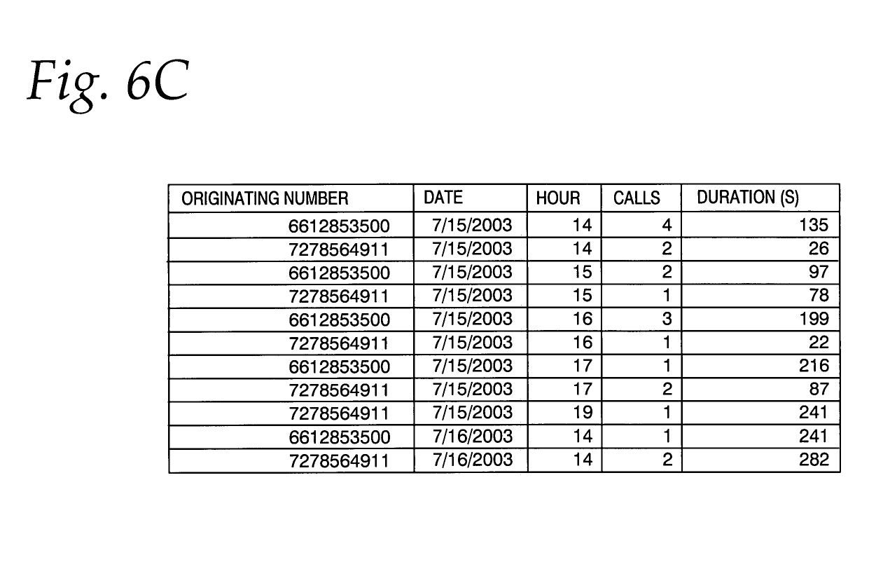

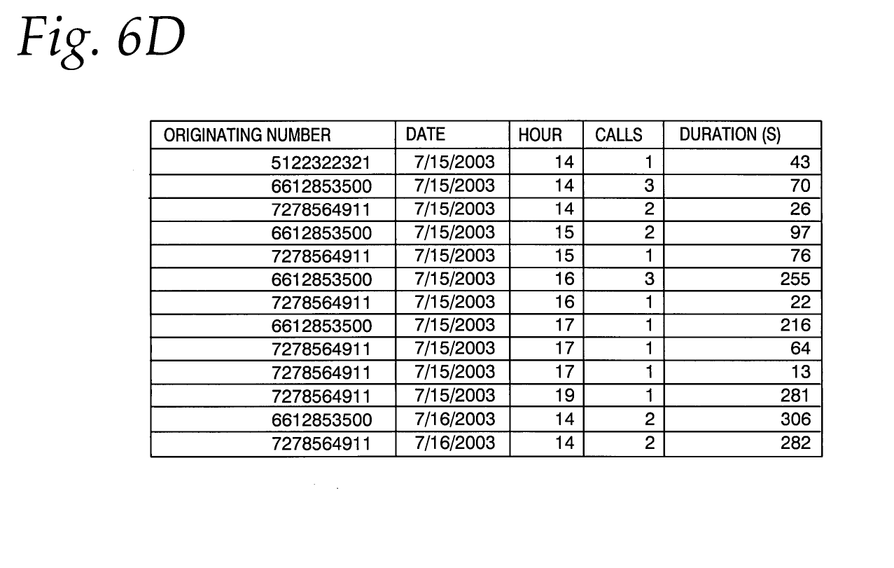

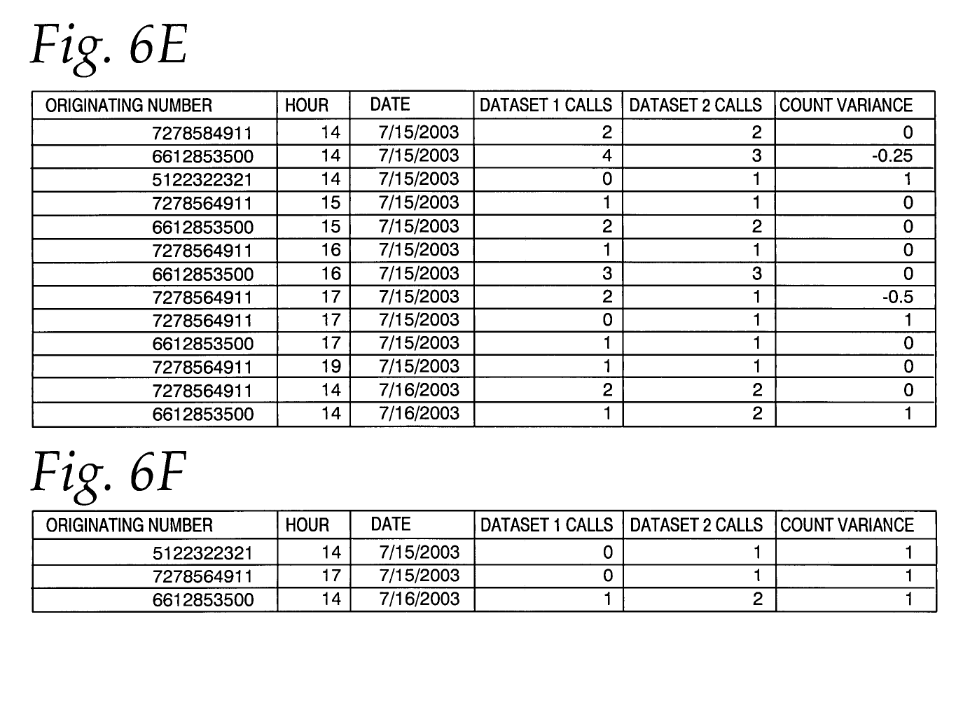

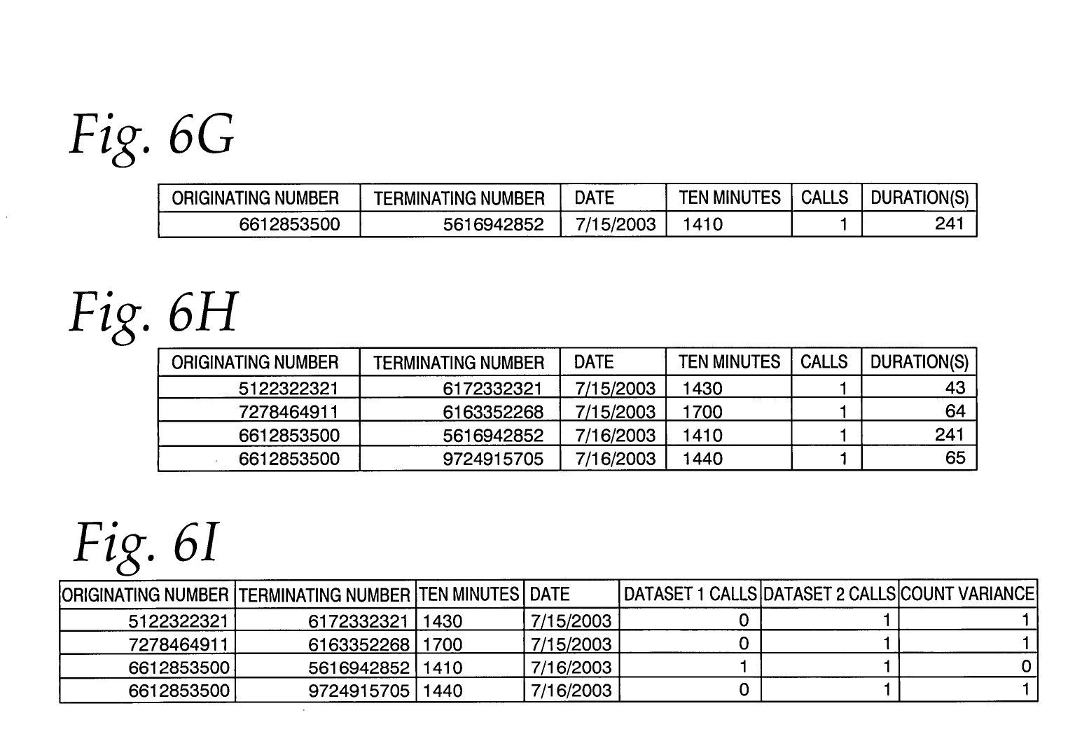

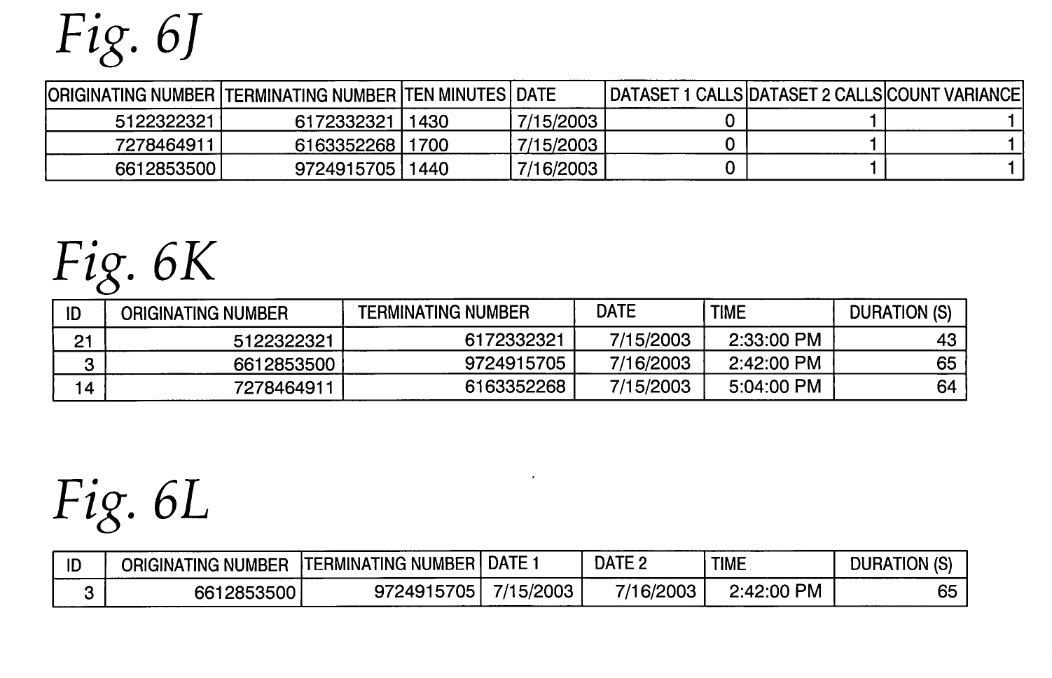

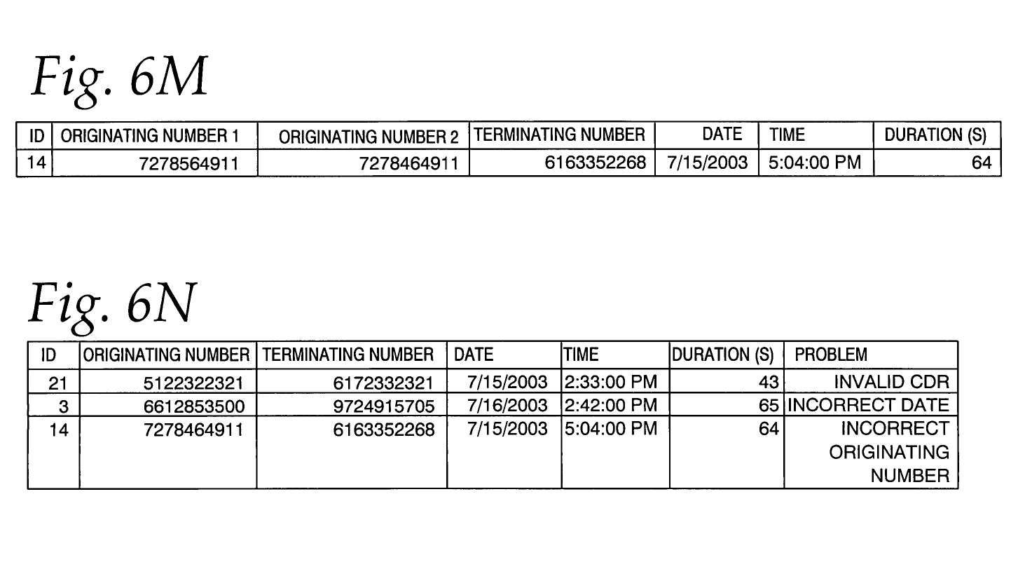

Referring, now to FIGS. 6A-N, one example of the execution of a top down process is described. FIGS. 6A-N represent results of the process to validate the “call count” information element in an invoice.

FIG. 6A shows a first data set, which includes a number of CDRs. Each entry represents a particular CDR and includes ID, originating number, terminating number, date, time, and duration. FIG. 6B shows a second data set and includes ID, originating number, terminating number, date, time, and duration.

FIGS. 6C and 6D show the results of grouping the data sets at a first level (level 1). The data sets have been grouped by originating number, date, and hour. Each entry represents this information and includes the total duration for records have the same originating number, date, and hour.

FIG. 6E represents a call comparison chart. This chart shows the set of first level groups (FIGS. 6C and D) when compared between the first data set and the second data set. FIG. 6F is a call variance chart and shows the set of first level groups that will receive a second level analysis. In this case, the first level count tolerance is set to 0+ variance, meaning that this is the set of groups where the call count for the second data set is at a greater value than the first data set.

FIGS. 6G and 6H represent the first and second data sets after a second level (level 2) grouping. Because most of the groups were within tolerance, only the CDRs brought out of the first level variance table are grouped at the second level grouping. The second level grouping uses all the first level grouping parameters, plus 10 minute grouping windows and terminating number as additional factors.

FIG. 6I is a call comparison chart of second level groups in each data set when compared to each other. FIG. 6J shows the second level call variance. This is the set of second level groups that will receive a third level of analysis. In this case, the second level count tolerance is set to 0+ variance. The number of calls in each group is now one, so that level three analysis is not needed. In other words, the CDRs are uniquely identified that may be potentially mismatched or faulty.

FIG. 6K shows a CDR validation set showing potentially mismatched or faulty CDRs. Since the set of questionable CDRs has been uniquely identified, in order to determine the cause of the error in each CDR, the questionable CDRs are compared against the first data set, starting with identical CDRs. Elements are eliminated singly, for example, only one element variance is acceptable, and confirming that there is not an identical element in the second data set.

In this case, the questionable CDRs in FIG. 6K are checked against the first data set (FIG. 6A) identically. That is, originating number, terminating number, date, time, and duration are checked to see if identical matches occur. No CDRs are found in the first data set.

Next, the questionable CDRs are checked against first data set without duration. No similar CDRs are found in the first data set. Next, the questionable CDRs are checked against the first data set without the time, but again with duration included. No similar CDRs are found.

Next, the date is eliminated and the time is included. A match is found. This match is compared against the original second data set to ensure that there is not an identical element in the second data set. This error is identified and the CDRs are eliminated from the data sets. After the CDR validation is complete, the analysis may be re-done without the CDR present, possibly with higher tolerances. Additionally, the analysis can be re-executed based upon durations and dollar values. FIG. 6L illustrates the result of the validation process for one of the potentially mismatched or faulty CDRs.

Now, two CDRs are remaining and the remaining questionable CDRs are compared to the first data set now including date again and eliminating terminating number. No matches are found.

Then, originating number is tested and a match for one of the CDRs is found as shown in FIG. 6M. As with the previous match, this CDR is confirmed against the original data set, eliminated, and reported.

With the one CDR remaining, all the fields have been compared and no similar CDRs have been found. If the system is configured to allow multiple data element variances, the system will now look at the remaining CDR eliminating two elements at a time. This makes the probability of finding a match higher, but decreases the probability that the match is actually referring to the same event. In this configuration, the CDR is considered completely invalid, eliminated, and reported. At this point, the system may be configured to re-run the remaining CDRs using higher tolerances or continue with the next analysis, such as cost or duration.

A final output is shown in FIG. 6N. This output identifies the CDRs that are invalid and the problem causing invalidity. The output may be used visually by a user to perform some action or automatically, for instance, to instruct a billing system not to pay for the questionable CDRs.

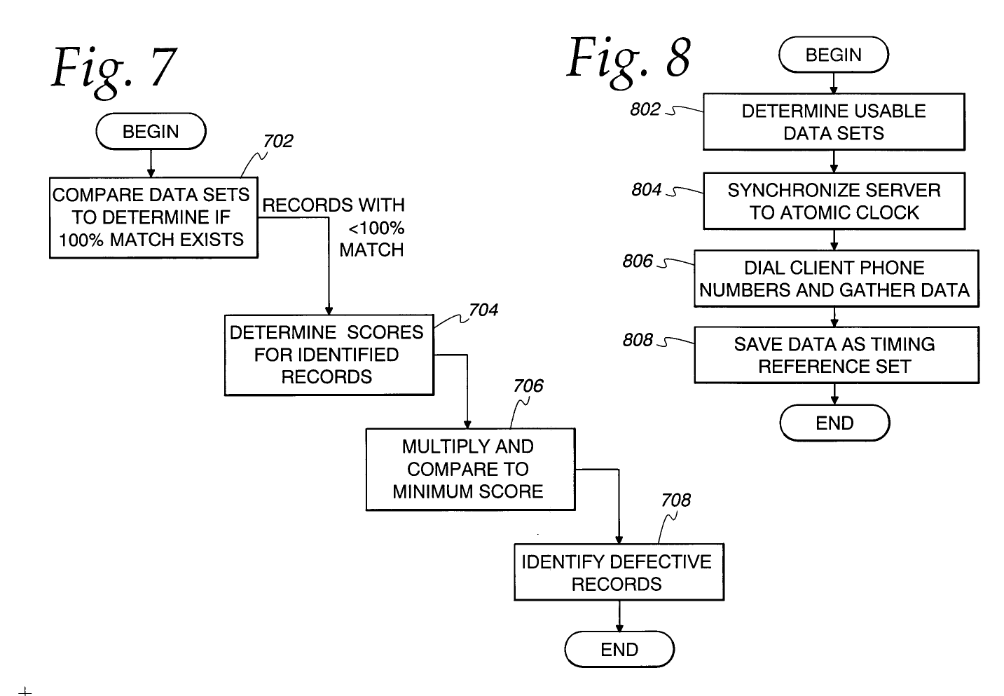

Referring now to FIG. 7, a bottom-up process for validating data is described. At step 702, comparison data sets are joined to a reference data set. In this step, comparisons are made between each CDR in the data set against each CDR in a reference set.

The data elements may be compared in different ways, depending on the variance rating each field can have. For example, a binary comparison may be made determining whether a data element is identical. For example, a toll free number may be allowed a variance of not even a single digit, since a different digit in the toll free number represents a completely different data element.

A numerical percentage method may also be used for comparisons. In this approach, a data element can vary by a certain percentage. Another method is using numerical values where the data element can vary by a certain explicit value. An example in telecommunication applications is duration where a five second variance may be acceptable to be considered the same call, but above that, it would be considered a different data element.

Another approach is to test string similarity (fuzzy logic) where the data element can vary physically, as long as the logical representation remains. For example, this field may represent a street address—if one data set refers to Main St. and the other to Main Street, these two data elements should be considered the same.

What is considered a 100 percent match and less than a 100 percent match may vary based upon the data field of the CDR. These definitions, along with a minimum score, may be defined when the system is configured.

The 100 percent match definition can represent the values that are considered to be identical. Preferably, the following information may be tested for a 100 percent match: origination switch and/or origination telephone number; termination switch and/or termination telephone number; time of call including the date; and duration. The less than 100 percent match definition may represent the definition of data elements that are not exactly identical, but that are scored as a probability of being the referenced data element. This is done by defining, for each data element, a function describing how to score the record. The function will include a worst case level of similarity to the comparison value and a function that describes how the worst case relates to the comparison value.

The less than 100 percent match definition may be used for the following types of information: origination switch and/or origination telephone number; termination switch and/or termination telephone number; time of call; and duration of call.

At step 704, the data similarity is slowly expanded and each data element within CDRs that have less than 100 percent similarity is given a score based upon a function used to score the element. For example, for origination switch and termination switch the multiplier may be 1 or 0. The multiplier for time of call may be 60 percent for the worst case, which occurs for a function where the standard deviation is five minutes from the value indicated in the reference data set. For duration, the multiplier may be 50 percent for the worst case, which occurs for a function where the standard deviation is 18 seconds from the value indicated in the reference data set.

At step 706, the scores are then multiplied together, and compared against the “minimum score”. If the score is lower than the minimum, the record is considered unacceptable. The multiplication ensures that more than one variable that is off causes a more pronounced effect on the result. In the above example, assuming the “minimum score” is set at 70 percent, if the origination number or termination number deviated by any amount, the CDR would be considered unacceptable. If the time of call deviated by fewer than five minutes, the multiplier would be the appropriate location of the curve. In addition, the scores may be combined using other mathematical operations.

Referring now to FIGS. 8-16, an example of a bottom-up process to determine potentially different data records is described. Although this process is described with respect to data records (i.e., CDRs) used in telecommunications, it will be understood that the process described can be applied to other applications not involving telecommunications. It will also be understood that once the process described has been completed, the scoring process described above can be used to determine if the records are indeed different and any required action can be taken.

Together, the processes of FIGS. 8-16 determine whether a record in a vendor supplied data set match any record (or are sufficiently similar to any record) in a reference data set. Thus, the vendor record is compared against all records in the reference set. The comparisons made are done using certain fields (e.g., time and duration). However, it will be understood that the identity and number of the fields compared may be changed depending upon the nature and informational content of the records being compared.

Referring now specifically to FIG. 8, an example of preprocessing and calibrating a system that performs matching and verification functions is described. At step 804, a server that is being used to perform the matching and verification functions is synchronized to an atomic clock. This step ensures that the server clock is set to a reliable and accurate time. At step 806, a phone number of the location of the client is dialed and a communication initiated with a client system, for example, a server at the client. In other words, a communication is established with a known client destination at a known time. The communication is recorded and tracked in the network, and timing information is gathered concerning the communication. At step 808, the information gathered is saved as a new record in a new data set, which can be compared to other records associated with the client. This timing data set is used to determine if the internal clocks in the client systems are correct and the corrections/adjustments needed if these clocks are incorrect. This process is repeated at regular time intervals to each location that will be matched in order to accurately establish variations.

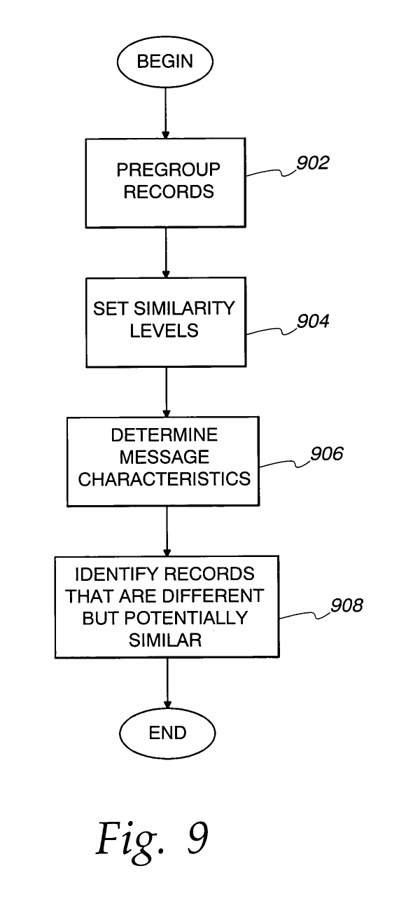

Referring now to FIG. 9, another example of a bottom-up process for performing matching functions in a telecommunication application is described. At step 902 groups of records are pre-grouped according to predetermined criteria. The pre-grouping is done to eliminate certain records so that processing speed and efficiency are enhanced. In one example, groups of records that a customer believes do not exist are eliminated from the data sets to be considered.

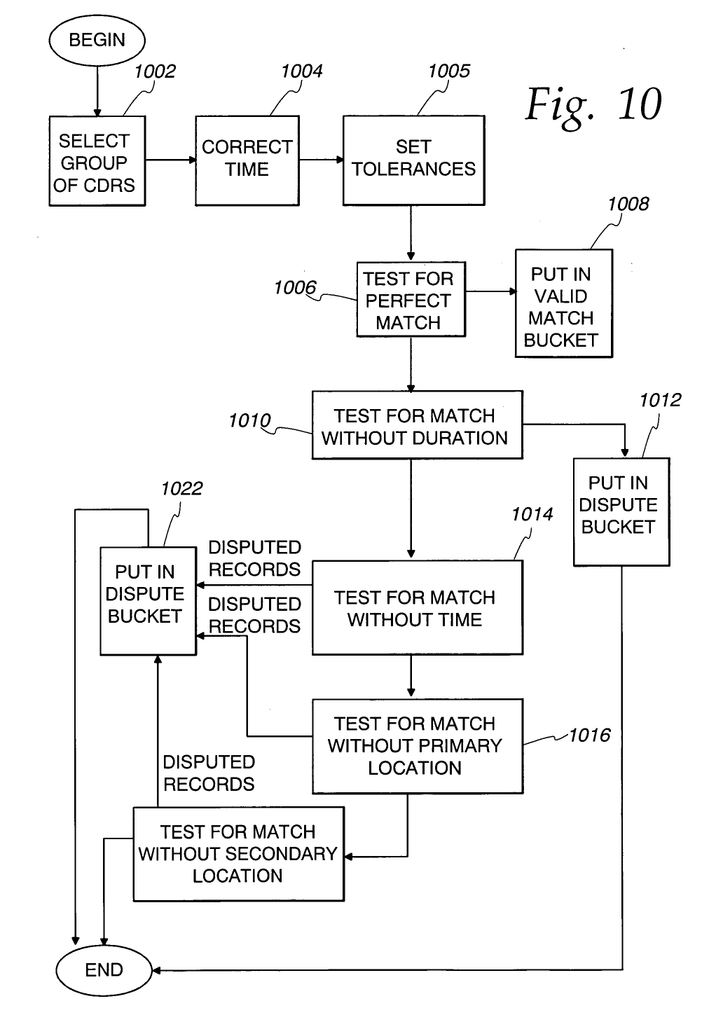

At step 904, similarity levels are set. In one example, the similarity levels are the time and duration tolerance. At step 906, it is determined whether the outbound message is domestic or international and whether the call will be a switched call or a dedicated call. Each of the data sets can be passed to step 908 independently to improve speed and efficiency of matching. At step 908, a process (described with respect to FIG. 10 below) is invoked to identify records that are different (i.e., do not match) but are sufficiently similar so that a reason for their dissimilarity may be identified.

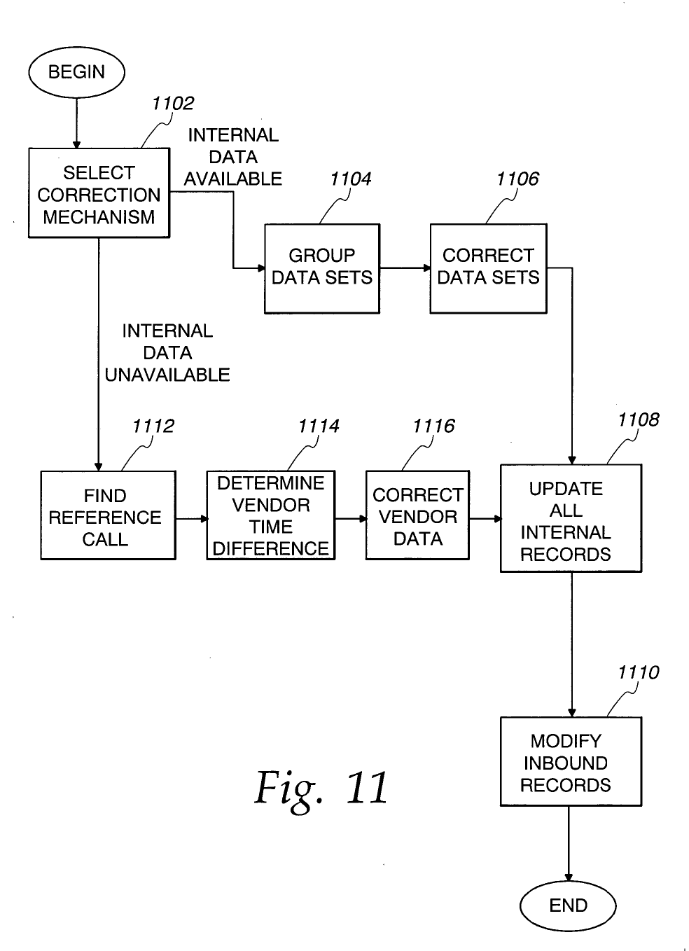

Referring now to FIG. 10, the process of step 908 is described in detail. At step 1002, a group of CDRs is selected. This selection may include the CDRs that have already been pregrouped according to the process of FIG. 8. At step 1004, a process is executed to correct the time of the records, if required. This process, described with respect to FIG. 11 below, determines any time correction needed on client CDRs that are to be evaluated. The data sets created with respect to FIG. 8 are used for this purpose.

At step 1005, tolerance times and durations are created for the records in the reference data set. These four new values are added to each of the reference records. The minimum time is set equal to the time of the reference record (in its time field) minus the time tolerance. The maximum time is set to be equal to the time of the reference records plus the time tolerance. The minimum duration is set to be equal to the duration of the reference record (in its duration field) minus the duration tolerance. The maximum duration is set to be equal to the duration plus the duration tolerance. These values are used in the matching procedures of steps described below.

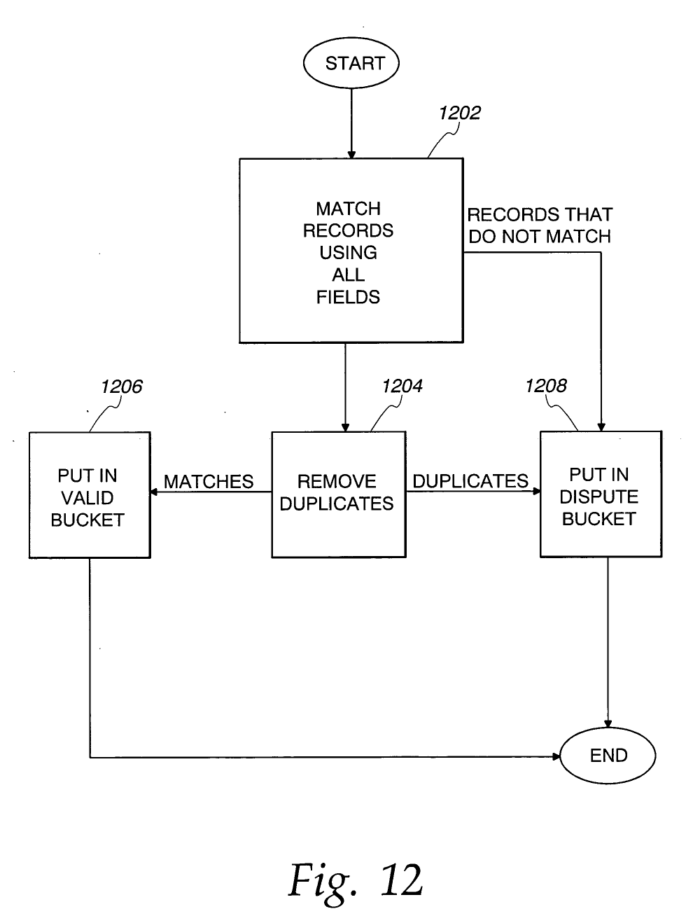

At step 1006, the system determines whether a perfect match exists between the record being examined and all records in the reference set. In other words, the system determines whether all specified fields (to be used in comparisons) in the vendor records match all those of a record in the reference set. This step is described in more detail with respect to FIG. 12 below. If a valid match is found, then at step 1008, the call record is placed in a valid match bucket, which stores pairs of CDRs (one from the reference set and one from the vendor set).

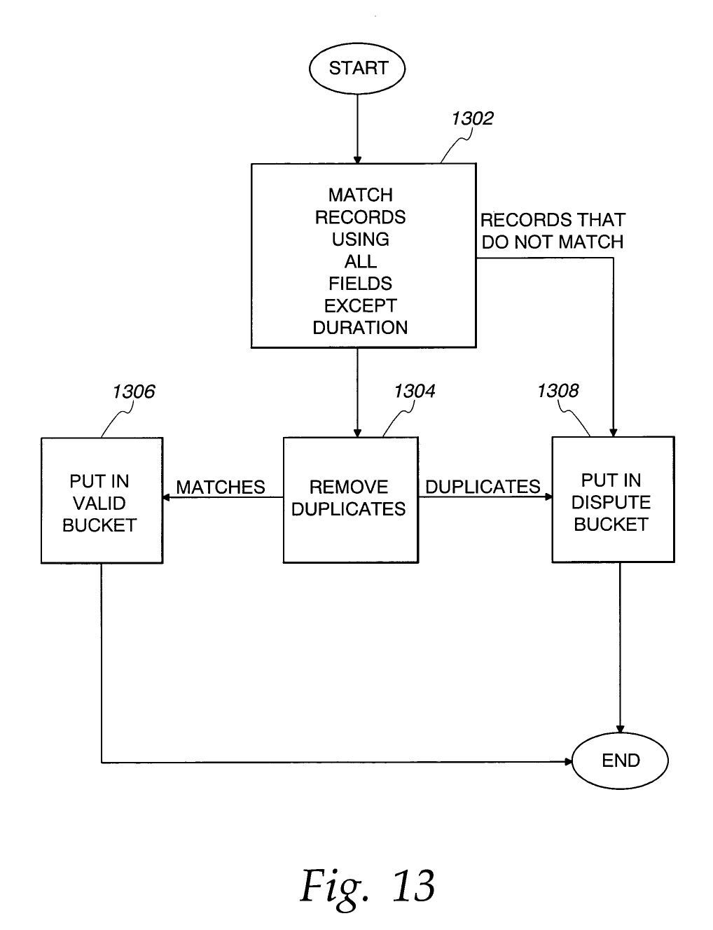

If a valid match is not found, then at step 1010 the system attempts to match the record to records in the reference set with duration field omitted or ignored. In other words, the system determines whether all fields of corresponding records match except the duration field. If matches are found at step 1010, at step 1012 the system determines if the vendor's duration is greater than or equal to the reference set duration. This step is described in greater detail with respect to FIG. 13 below. If the answer is affirmative, then the record is placed in the dispute bucket at step 1020 and the reason is identified as that the call duration is overstated.

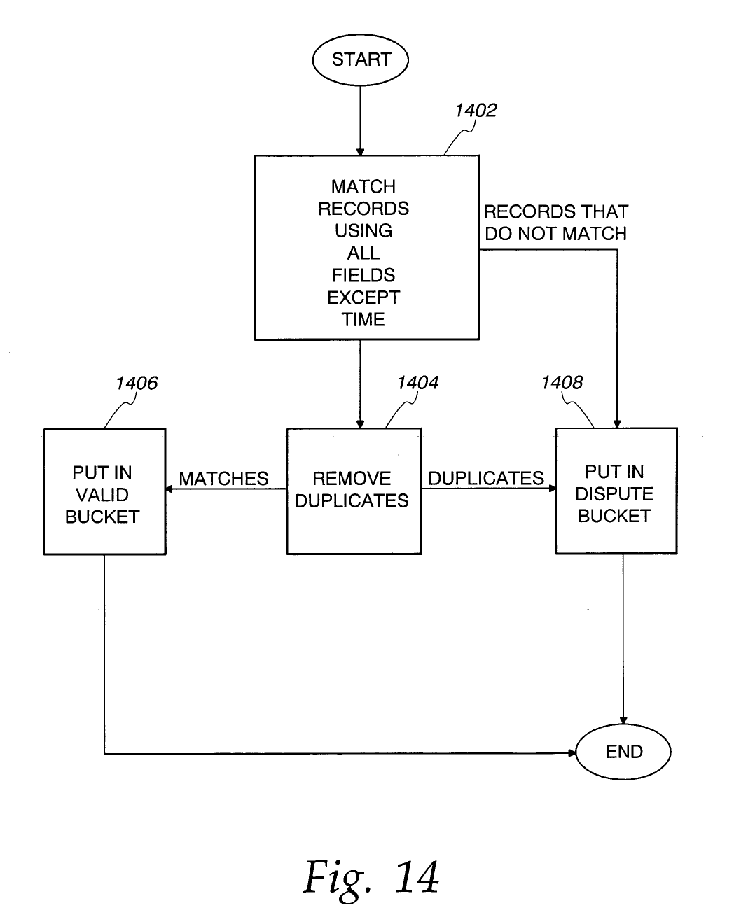

If no matches are found at step 1010, then execution continues at step 1014. At step 1014, the system attempts to match the record to all records in the reference set with the time field omitted. In other words, the system determines whether all fields of the corresponding record in the reference set match except the time field. This step is described in greater detail with respect to FIG. 14 below. If a match is found, then the records are placed in a dispute bucket at step 1022 and the reason is identified as the call did not occur at the time stated. The dispute bucket stores the pairs of records which represent records that likely represent the same occurrence, despite the differences that exist in the records.

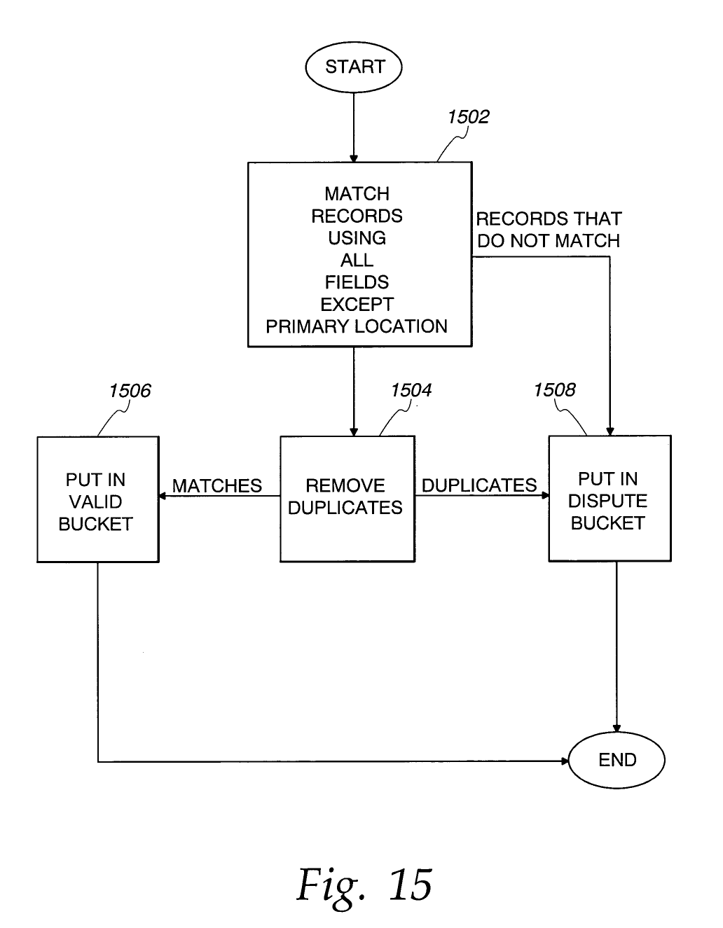

If no matches are found at step 1014, then execution continues at step 1016. At step 1016, the system attempts to match the record to all records in the reference set with the primary location field omitted. For outbound calls, the primary location field is an origination identifier, for example, the originating telephone number or the originating trunk number. For inbound calls, the order is reversed. In this case, the system determines whether all fields of corresponding records match except the primary location field. This step is described in greater detail with respect to FIG. 15 below. If records are found, then the records are placed in the dispute bucket at step 1022 and the reason is identified as that the call was not made with primary location.

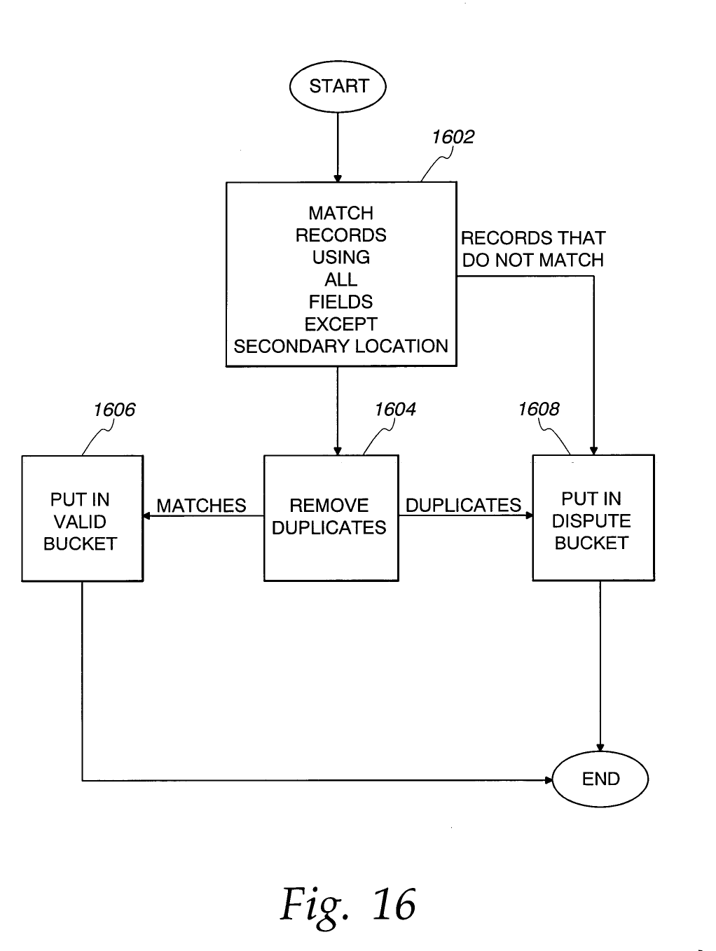

If no matches are found at step 1016, then execution continues at step 1018. At step 1018, the system attempts to match the record to all records in the reference set with secondary location field omitted. The secondary location field is a termination identifier such as the terminating telephone number or terminating trunk number. For inbound calls, the order is reversed. In this case, the system determines whether all fields of corresponding records match except the secondary location field. This step is described in greater detail with respect to FIG. 16 below. If records are found, then the records are placed in the dispute bucket at step 1022 and the reason is identified as call was not made with secondary location.

The above example attempted to find similar records when a single characteristic (e.g., time or duration) is ignored. However, it will be understood that multiple characteristics may also be ignored (e.g., time and duration simultaneously) in other examples.

Referring now to FIG. 11, step 1004 of FIG. 10 is described. At step 1102, the system determines the time correction mechanism based upon the available data. This determination is based upon whether internal data (as determined in FIG. 8) is available. If the internal data is not available, at step 1104, separate data sets are grouped into days and the average time difference per location per day is determined. This can be done by subtracting the average vendor time from the average internal time. At step 1106, correct vendor data by adding the time difference to the data set. At step 1108, all the internal records less than a minimum duration are updated to that minimum duration. This number is variable and depends upon the attributes of a particular vendor. This is done to take minimum billing requirements into account, and can be eliminated dependent on the specific agreements regarding minimum billing requirements.

At step 1110, all inbound vendor records are modified by determining the time zone difference from the origination point to the termination point of the call. In addition, the time of the call origination is corrected by adding the time zone difference to it. Execution then ends.

If reference data exists, at step 1112, each reference call from the test set created in FIG. 8 is found in the inbound vendor data set by matching the termination location, the originating phone number, and the time with a high tolerance, such as half of the time between time checks.

At step 1114, the vendor time difference per location per time period is determined. This may be accomplished by subtracting the reference time from the test set (created in FIG. 8) from the internal time.

At step 1116, the internal data is corrected by adding the time difference to the vendor data set for all calls that fall within the range of the vendor time plus or minus one-half of the time correction interval. Control continues at step 1108 as described above.

Referring now to FIG. 12, step 1006 of FIG. 10 is described in detail. At step 1202, the system determines if a match is has been found between all fields of the data record in the vendor set and all fields of a record in the reference set. For example, the system attempts to match the vendor primary location field to the internal primary location field. In addition, it is determined if the vendor secondary location field in the vendor record matches the secondary location field of a record in the reference set. Further, it is determined if the time field in the vendor record in the vendor data set is greater than or equal to the minimum time in the internal data set. It is also determined if the time field in the vendor data set is less than or equal to the maximum time in the internal data set. In addition, it is determined if the duration in the vendor data set is greater than or equal to the minimum duration in the internal data set. Furthermore, it is determined if the duration in the vendor data set is less than or equal to the maximum duration in the internal data set.

If matches are found, then at step 1204, any duplicate CDRs are removed. This ensures that each CDR is counted only once and matches one and only one record. At step 1206, the CDR is placed in the valid match bucket.

If no matches are found, then at step 1206, the CDR set (one from the reference set and one from the vendor) are placed in the Dispute CDRs in Progress bucket. A dispute resolution procedure can then be invoked to further process these records.

Referring now to FIG. 13, step 1010 of FIG. 10 is described in detail. At step 1302, the procedure determines if a match is found by omitting a comparison of duration fields. Specifically, the system attempts to match the vendor and reference record primary and secondary location fields. In addition, it is determined if the time in the vendor data set record is greater than or equal to the minimum time in the reference data set record. It is also determined if the time in the vendor data set record is less than or equal to the maximum time in the record data set record.

If matches are found, then at step 1304, any duplicate CDRs are removed. This ensures that each CDR is counted only once and matches one and only one record. At step 1306, the CDR is placed in the valid match bucket.

If no matches are found, then at step 1308, the CDR set (one from the reference set and one from the vendor) are placed in the Dispute CDRs in Progress bucket. A dispute resolution procedure can then be invoked.

Referring now to FIG. 14, step 1014 of FIG. 10 is described in detail. At step 1402, the procedure determines if a match is found. Specifically, the system attempts to match the vendor and reference record primary and secondary location fields. In addition, it is determined if the duration in the vendor data set is greater than or equal to the minimum duration in the internal data set. Furthermore, it is determined if the duration in the vendor data set is less than or equal to the maximum duration in the internal data set. The primary and secondary locations of the vendor record are matched against these fields of records in the reference set.

If matches are found, then at step 1404, any duplicate CDRs are removed. This ensures that each CDR is counted only once and matches one and only one record. At step 1406, the CDR is placed in the valid match bucket.

If no matches are found, then at step 1408, the CDR set (one from the reference set and one from the vendor) are placed in the Dispute CDRs in Progress bucket.

Referring now to FIG. 15, step 1016 of FIG. 10 is described in detail. At step 1502, the procedure determines if a match is found. Specifically, it is determined if the vendor secondary location in the vendor record matches the secondary location in the reference set record. Also, it is determined if the time in the vendor data set record is greater than or equal to the minimum time in the internal data set record. It is also determined if the time in the vendor data set record is less than or equal to the maximum time in the internal data set record. In addition, it is determined if the duration in the vendor data set record is greater than or equal to the minimum duration in the internal data set record. Furthermore, it is determined if the duration in the vendor data set record is less than or equal to the maximum duration in the internal data set record.

If matches are found, then at step 1504, any duplicate CDRs are removed. This ensures that each CDR is counted only once and matches one and only one record. At step 1506, the CDR is placed in the valid match bucket.

If no matches are found, then at step 1508, the CDR set (one from the reference set and one from the vendor) are placed in the Dispute CDRs in Progress bucket.

Referring now to FIG. 16, step 1018 of FIG. 10 is described in detail. At step 1602, the procedure determines if a match is found. Specifically, the system attempts to match the vendor primary location in the vendor record to the primary location in the reference set record. It is also determined if the time in the vendor data set record is less than or equal to the maximum time in the internal data set record. In addition, it is determined if the duration in the vendor data set record is greater than or equal to the minimum duration in the internal data set record. Furthermore, it is determined if the duration in the vendor data set record is less than or equal to the maximum duration in the internal data set record.

If matches are found, then at step 1604, any duplicate CDRs are removed. This ensures that each CDR is counted only once and matches one and only one record. At step 1606, the CDR is placed in the valid match bucket.

If no matches are found, then at step 1608, the CDR set (one from the reference set and one from the vendor) are placed in the Dispute CDRs in Progress bucket.

While there have been illustrated and described particular embodiments of the present invention, it will be appreciated that numerous changes and modifications will occur to those skilled in the art, and it is intended in the appended claims to cover all those changes and modifications which fall within the true spirit and scope of the present invention.

1. A method for determining the similarity of data records in first and second data sets, the data records having an informational content, the method comprising:
identifying a first data record in the first data set that is potentially identical to a second data record in the second data set, the identified first and second data records having an informational content that is non-identical but similar;
determining whether the first and second data records identified as potentially identical are truly identical based upon a predetermined criteria.

2. The method of claim 1 wherein identifying a first and second data records identifies telecommunication call detail records (CDRs).

3. The method of claim 1 wherein identifying a first data record and a second data record includes grouping the records in the first and second data sets into groups based upon a predetermined criteria.

4. The method of claim 1 wherein identifying includes comparing the informational content of first data record to the informational content of the second data record.

5. A method for determining different data records in a telecommunications system from records in first and second data sets in a comprising:
identifying potentially different data records in the first data set at least in part by comparing records in the first data set to records in the second data set; and
verifying that the potentially different records identified as potentially different are truly different using at least one predetermined criteria.

6. The method of claim 5 wherein the different data records can be faulty data records or mismatched data records.

7. The method of claim 5 wherein determining potentially different data records includes defining a set of similarity characteristics, grouping the data records in each of the first and second sets according to the similarity characteristics into similarity groups, and comparing the similarity groups in the first data set to the similarity groups in the second data set.

8. The method of claim 5 wherein determining potentially different data records includes determining whether each record in the first data set completely matches with a data record in the second data set.

9. The method of claim 5 wherein verifying includes determining from the second data set a set of data records that are similar to the potentially different record identified in the first data set.

10. The method of claim 5 wherein verifying includes scoring elements of each of the plurality of data records to form a plurality of scores, multiplying the plurality of scores to form a test score, comparing the test score to a predetermined minimum score, and determining a different record if the comparison determines the test score is unacceptable.

11. The method of claim 5 further comprising taking an action relating to the different data records.

12. A device for determining faulty data records in a telecommunications system from records in first and second data sets in a comprising:
a data store containing first and second data sets; and
a processor coupled to the data store and having an output,
such that the processor identifies potentially different data records in the first data set at least in part by comparing records in the first data set to records in the second data set and verifies that the potentially different records identified as potentially different are different using at least one predetermined criteria and identifies the different records on the output.

13. The device of claim 12 wherein the processor includes means for defining a set of similarity characteristics, means for grouping the data records in each of the first and second sets according to the similarity characteristics into similarity groups, and means for comparing the similarity groups in the first data set to the similarity groups in the second data set.

14. The device of claim 12 wherein the processor includes means for determining whether each record in the first data set completely matches with a data record in the second data set.

15. The device of claim 12 wherein the processor includes means for determining from the second data set a set of data records that are similar to the potentially faulty record identified in the first data set.

16. The device of claim 12 wherein the processor includes means for scoring elements of each of the plurality of data records to form a plurality of scores, means for multiplying the plurality of scores to form a test score, means for comparing the test score to a predetermined minimum score, and means for determining a different record if the comparison determines the test score is unacceptable.

17. The device of claim 12 wherein the different data records can be faulty data records or mismatched data records.
